(19) United States
(12) Patent Application Publication
(10) Pub. No.: US 2016/0181470 A1
(43) Pub. Date: Jun. 23, 2016

(54) HIGH PEAK POWER QUANTUM CASCADE SUPERLUMINESCENT EMITTER

(71) Applicant: TRUSTEES OF PRINCETON UNIVERSITY, Princeton, NJ (US)

(72) Inventors: Claire GMACHL, Princeton, NJ (US); Nyan LYnn AUNG, Schenectady, NY (US); Mei Chai ZHENG, Princeton, NJ (US)

(21) Appl. No.: 14/974,870

(22) Filed: Dec. 18, 2015

Related U.S. Application Data
(60) Provisional application No. 62/093,637, filed on Dec. 18, 2014.

(51) Int. Cl. H01L 33/00; H01L 33/48; H01L 33/44

(52) U.S. Cl. CPC H01L 33/0045; H01L 33/44; H01L 33/483; H01L 33/005; H01L 2933/0033; H01L 2933/0025

(57) ABSTRACT

A high power quantum cascade superluminescent emitter employs low reflectivity facets including a tilted cleaved facet, a rounded shaped wet-etched sloped facet and a loop facet in either a linear or spiral configuration to increase ASE.

### CROSS-REFERENCE TO RELATED APPLICATIONS

This application is based on, and claims priority to, U.S. Provisional Application No. 62/093,637, filed Dec. 18, 2014, the entire contents of which being fully incorporated herein by reference.

### STATEMENT OF GOVERNMENT INTEREST

This invention was made with government support under MIRTHE (NSF-ERC) (ECC #0540832) and NDSEG Fellowship (32 CFR 168 a). The U.S. government has certain rights in the invention.

### FIELD OF INVENTION

In general, the invention relates generally to quantum cascade devices. In more detail, the invention relates to a high power quantum cascade superluminescent emitter.

### BACKGROUND

Superluminescent (“SL”) emitters with low temporal and high spatial coherence have found applications in medical imaging and industrial process monitoring. A particular example of an application using such light sources that emit in the near-infrared is in optical coherence tomography (“OCT”) for real-time 3D imaging of the human eye. Extending OCT into the mid-infrared (“mid-IR”) region can enable a hyperspectral imaging system that can visualize deep structures such as microchannels inside ceramics and differentiate between biological compounds such as healthy and cancerous tissues. In particular, extending OCT to the mid-IR will potentially expand biomedical imaging to cancerous tissues and compounds such as collagen amide, phosphate and carbonate, which have strong absorption spectra in the mid-IR. Mid-IR OCT systems can also aid in industrial process monitoring. However, the lack of an appropriate high power, low coherent mid-IR light source has prevented the realization of mid-IR OCT systems.

Quantum cascade (“QC”) devices present themselves as potential superluminescent light sources in the mid-IR and therefore provide a possible light source for mid-IR OCT. Realizing a compact and low cost mid-IR light source practical for these applications requires the development of milliwatt level QC superluminescent (“QCSL”) devices, which operate at room temperature. However, it is challenging to achieve milliwatts of SL power in QCSL devices due to low spontaneous emissions caused by the short non-radiative carrier lifetime of the intersubband transitions.

The effect of a tilted front facet on the device performance of QC lasers has previously been studied and the use of a 17° tilted angle was found to reduce the front facet's reflectivity by up to approximately 10⁻² without significantly compromising the slope efficiency. In addition, attempts to generate superluminescence from QC lasers through suppressing the laser action in a 2 mm long Fabry-Perot cavity by replacing one of the cleaved facets with a wet-etched sloped facet yield a peak optical power of 25 μW at 10 K. However, none of these approaches have yielded sufficient optical power via amplified spontaneous emission (“ASE”) in QC emitters.

### SUMMARY OF INVENTION

A quantum cascade emitter comprises a cavity comprised of a semiconductor material, a first low-reflectivity facet coupled to a first end of said cavity, and a second low-reflectivity facet coupled to a second end of the cavity.

A method for generating a high power superluminescent light in a quantum cascade device comprises terminating a semiconductor cavity at a first end with a rounded shaped wet-etched sloped facet and terminating said semiconductor cavity at a second end with a tilted cleaved facet, second tilted cleaved facet allowing light to exit from said cavity.

A quantum cascade emitter comprises a spiral cavity comprised of a semiconductor material, a first low-reflectivity facet coupled to a first end of said spiral cavity; and a second low-reflectivity element coupled to a second end of said spiral cavity.

### BRIEF DESCRIPTION OF DRAWINGS

FIG. 1A depicts an exemplary embodiment of a QCSL emitter employing low-reflectivity facets.

FIG. 1B depicts an exemplary embodiment of a QCSL emitter employing a linear semiconductor cavity, a tilted cleaved facet and a rounded shaped wet-etched sloped facet.

FIG. 1C is a scanning electron microscope of a portion of semiconductor cavity 102 coupled to RSWESF 104 according to one embodiment.

FIG. 1D shows an exemplary QC band structure at an applied electric field of 95 kV cm⁻¹ for a QCSL emitter device utilizing a linear geometry for approximately 5 μm wavelength emission according to one embodiment.

FIG. 1E a shows a representative pulsed light, current, and voltage characteristic of a 15 μm wide and 8 mm long tilted linear QCSL device employing a TCF front facet and a RCWESF back facet at various temperatures according to one embodiment.

FIG. 1F shows a far-field intensity pattern of a linear QCSL device employing a TCF front facet and a RSWESF back facet according to one embodiment.

FIG. 1G is a plot showing a comparison of superluminescence output power for a 25 μm wide and 8 mm long linear QCSL device employing a TCF front facet and a RCWESF back facet that is AR coated and one that is not AR coated at various temperatures according to one embodiment.

FIG. 1H shows various plots of emission spectra for a QCSL device employing a TCF front facet and a RCWESF back facet according to one embodiment.

FIG. 2A depicts a superluminescent spiral cavity coupled to two low-reflectivity facets according to one embodiment.

FIG. 2B shows optical images of QCSL devices employing a spiral cavity of 8 mm and 12 mm as well as far-field intensity measurements for these devices according to one embodiment.

FIG. 2C is a plot of peak power vs. current taken under pulsed operation (100 ns pulse width at 5 kHz) across different temperatures for an 8 mm QCSL device and 12 mm QCSL device both employing spiral cavities and a RSWESF according to one embodiment.

FIG. 2D is a plot of superluminescence power of a QCSL device employing a spiral cavity and a RSWESF taken at approximately 20 mA below the laser threshold vs. temperature.

FIG. 2E shows plots of ASE spectra and interferograms at approximately 20 mA below threshold for 8 mm and 12 mm SCSL devices employing a spiral cavity and an RSWESF according to one embodiment.

FIG. 2F is a plot of coherence length vs. peak power of a 12 mm QCSL device employing a spiral cavity and RSWESF at 200 K according to one embodiment. The “X” marks the laser threshold.

FIG. 3A is an optical image of several different portions of spiral cavity QCSL devices joined to non-tilted ridge waveguides according to one embodiment.

FIG. 3B shows microscope images of a portion of two QCSL devices employing spiral cavities and a passive loop back facet with a total length of 12 mm (left) and 16 mm (right).

FIG. 3C is a plot of the threshold current density vs. temperature comparing QCSL devices employing a spiral cavity and an AR RSWESF, a passive loop back facet without metal and a passive loop back facet with metal according to one embodiment.

FIG. 3D shows plots of peak power vs. current a 12 mm and 16 mm QCSL device employing a spiral cavity and a passive loop back facet according to one embodiment.

FIG. 3E show ASE spectra and interferograms at various temperatures of a 12 mm and 16 mm QCSL device employing a spiral cavity and a passive loop back facet according to one embodiment.

### DETAILED DESCRIPTION

Applicants have developed an apparatus and method for generating high peak power in a QCSL device by employing a semiconductor cavity coupled to a low reflectivity front facet and a low reflectivity back facet. Applicants have realized several QCSL high power designs described herein: (1) a linear geometry with a tilted cleaved facet and a rounded shaped wet-etched sloped facet; (2) a spiral geometry with a tilted cleaved facet and a rounded shaped wet-etched sloped facet and (3) a spiral geometry with a tilted cleaved facet and a rounded shaped passive loop facet.

As will become evident as the invention is further described, Applicants have devised an apparatus and method that yields at least a three order of magnitude improvement in superluminescence output power in QC emitters by designing the cavity made from the combination of a 17° tilted cleaved facet and a rounded shaped wet-etched sloped facet. Such a design can greatly reduce the optical feedback, suppressing the lasing and thus generating high power superluminescence. According to alternative embodiments, the output power may be further enhanced by the addition of Si₃N₄ layer on the rounded shaped we-etched sloped facet as an anti-reflection coating. This enables realization of more than 10 milliwatt output power of superluminescence. Further, according to certain embodiments, by employing the spiral cavity, longer devices can be fabricated more compactly, which enables realization of more than 30 mW of superluminescent power.

The maximum superluminescence output power for a QCSL device may be achieved at laser threshold. A large cavity and low facet reflectivities are required to generate high power superluminescence from QCSL devices. Due to these requirements, QCSL devices intrinsically have high laser thresholds, which should be maintained within the limitations of the available current source. Because the the laser threshold current density does not change significantly with the width of the cavity but decreases with the inverse of the length of the cavity, for a given area of device, a thinner and longer cavity is more suitable than a wider and shorter device to achieve maximum ASE at room temperature within the current source limitations.

The maximum ASE output intensity originating from a spontaneously emitting point source Iₛₚₒₙ a distance 1 away from the front facet with a reflectivity RF occurs at the lasing threshold and behaves as:

$${I}_{max} ( l ) = ( 1 - {R}_{f} ) {I}_{spon} \frac{( {e}^{C} - 1 ) l}{C}$$

where

$$C = \frac{1}{2} ( ln ( \frac{1}{{R}_{f} {R}_{b}} ) )$$

and Rf and Rb are the respective reflectivities of the front and back facets coupled to the semiconductor cavity.

Because the ASE output power is linearly proportional to the length of the cavity, 1, it is desirable to increase the length of the cavity to achieve greater power. However, it is also desirable to also maintain a compact design as longer devices are impractical and introduce additional fragility. Furthermore, in order to prevent operation in the lasing regime and thus generate high power superluminescence, it is desirable to minimize the reflectivities of the front and back facets.

I. High Peak Power QC Emitter

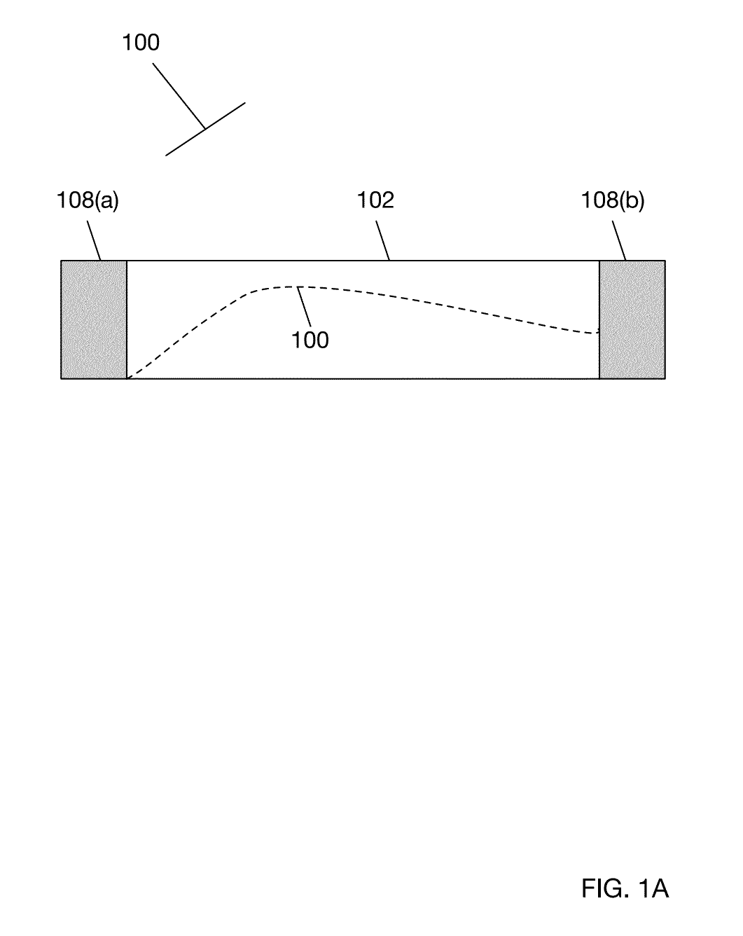

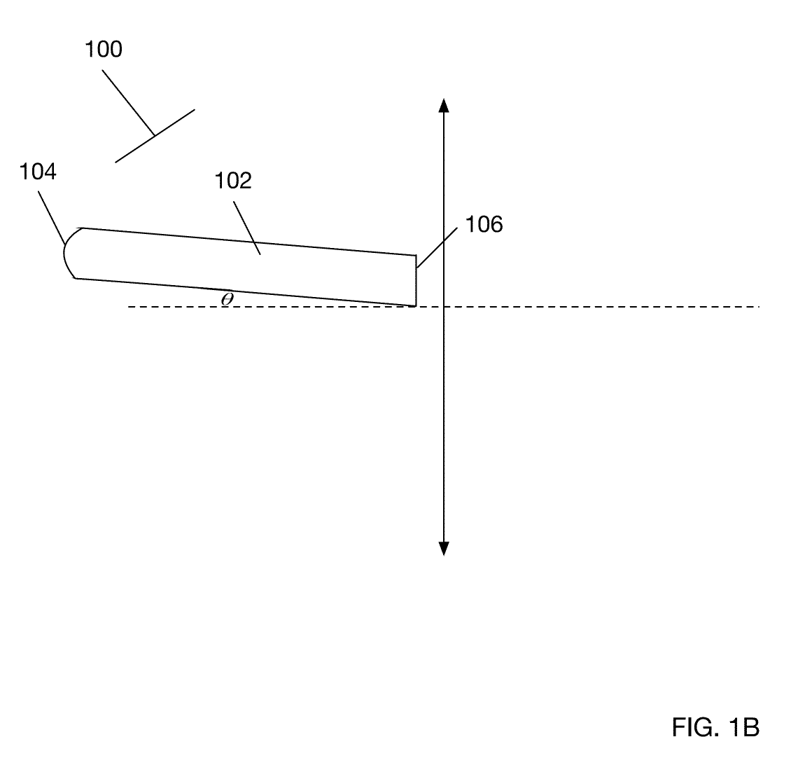

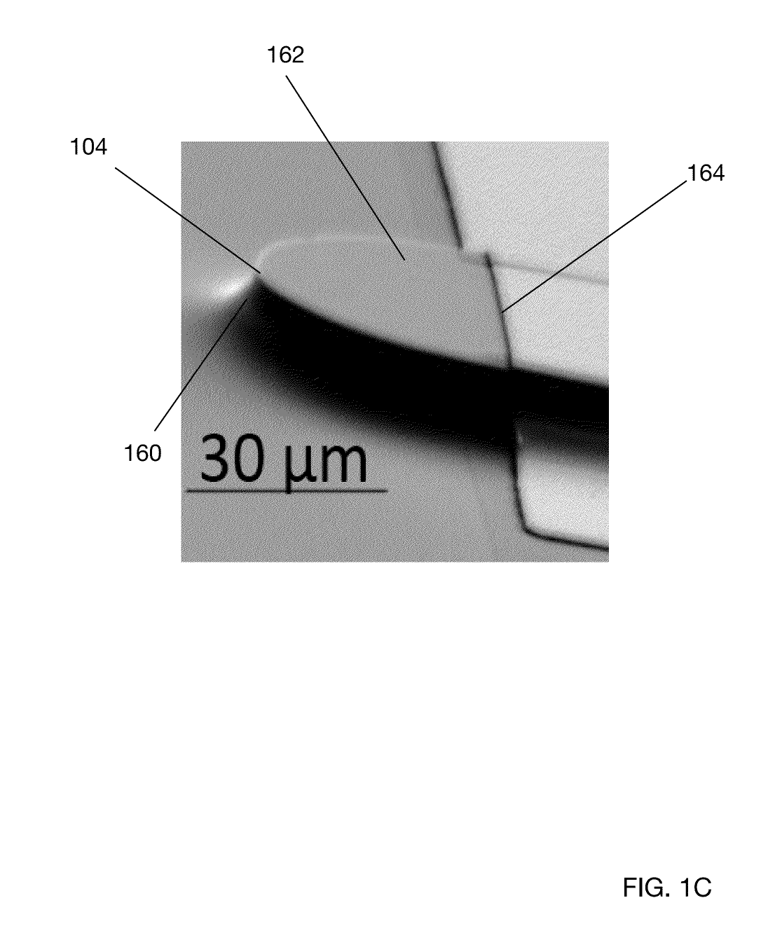

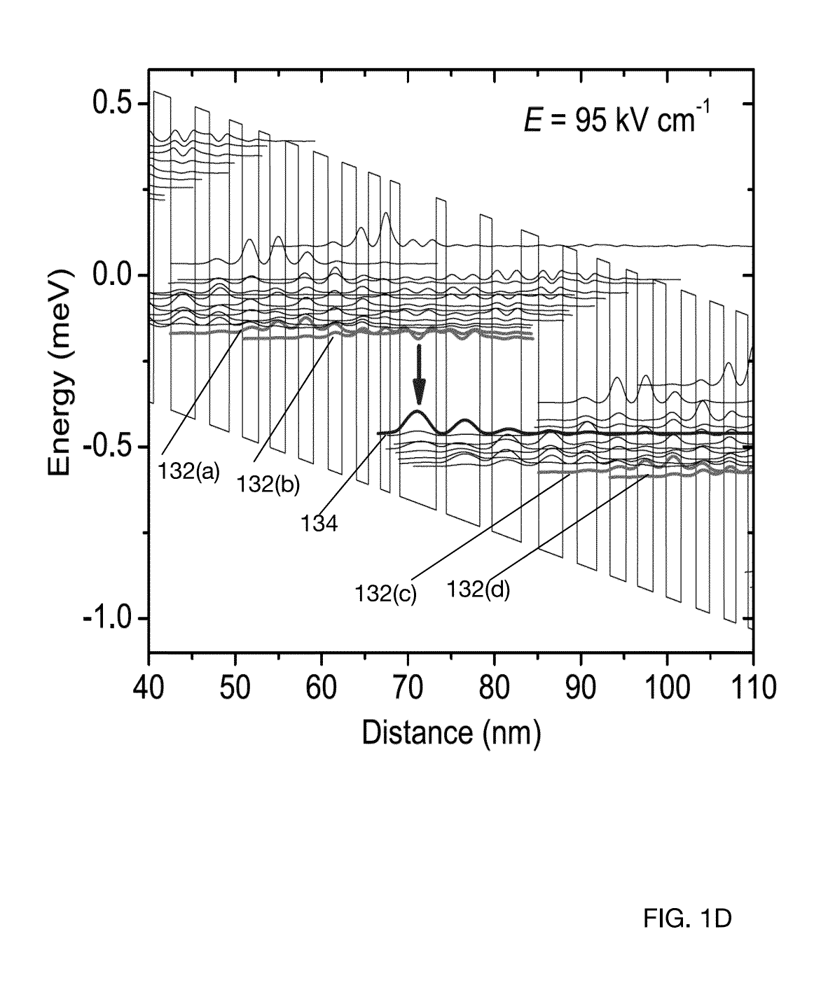

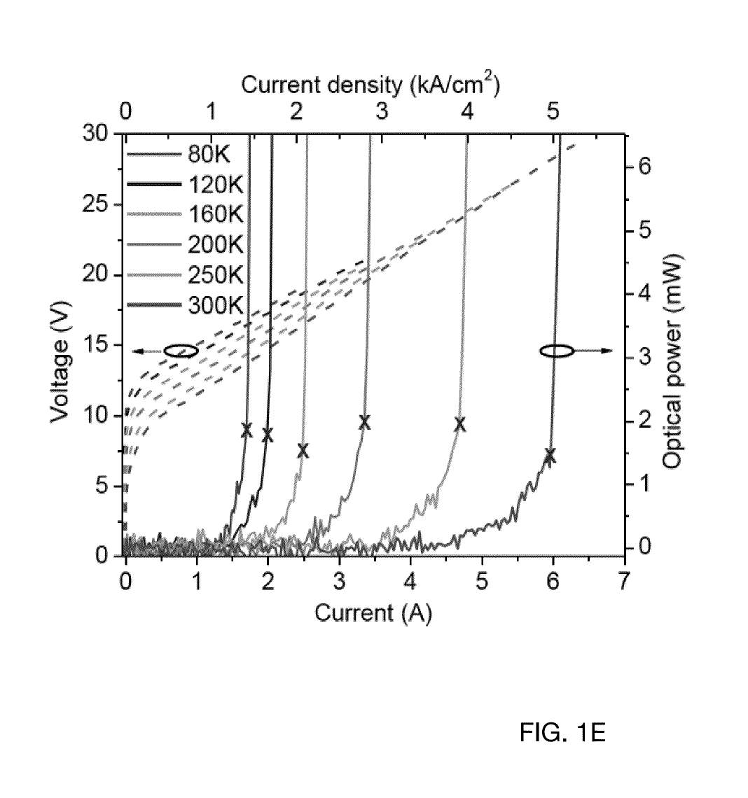

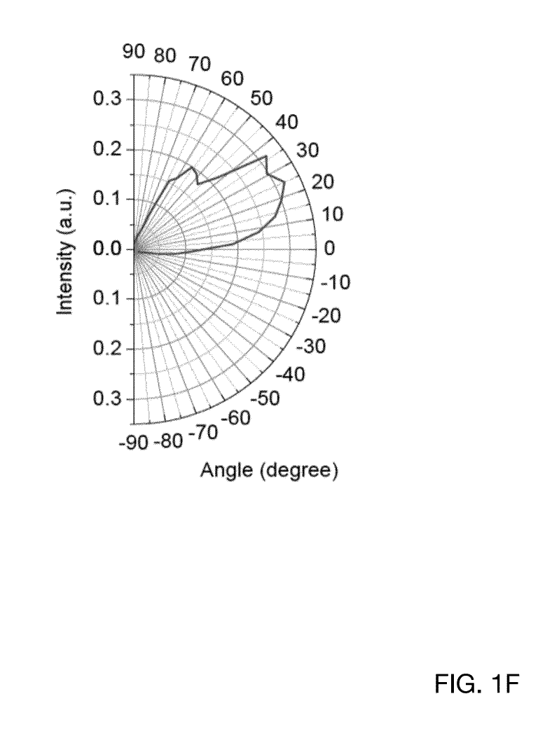

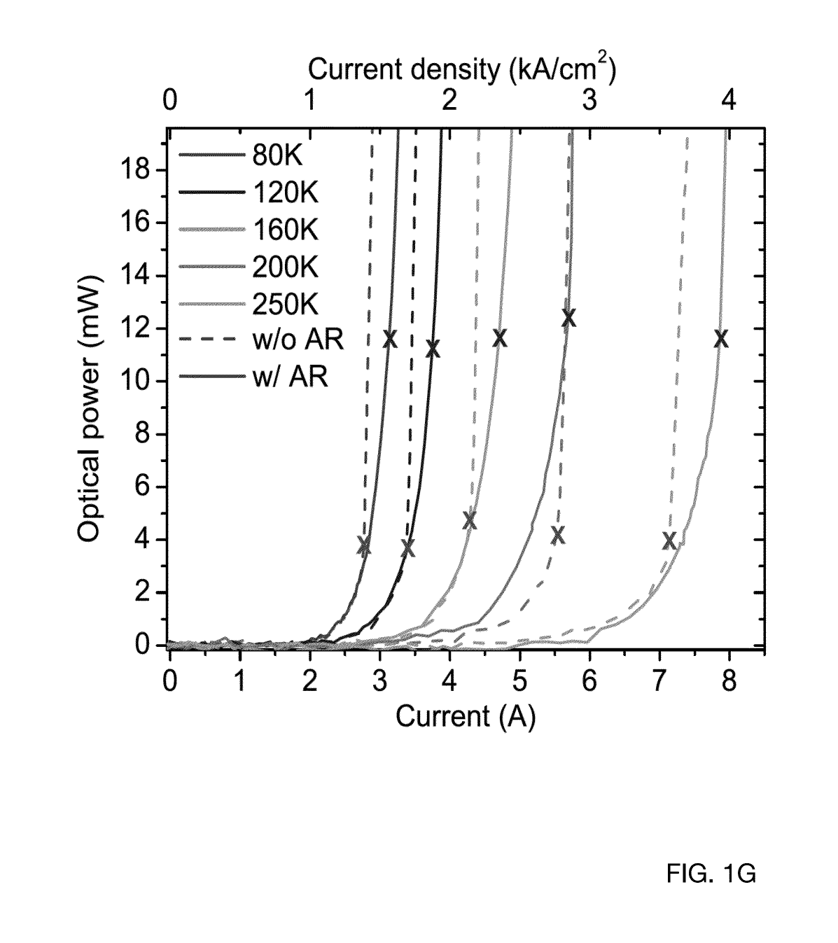

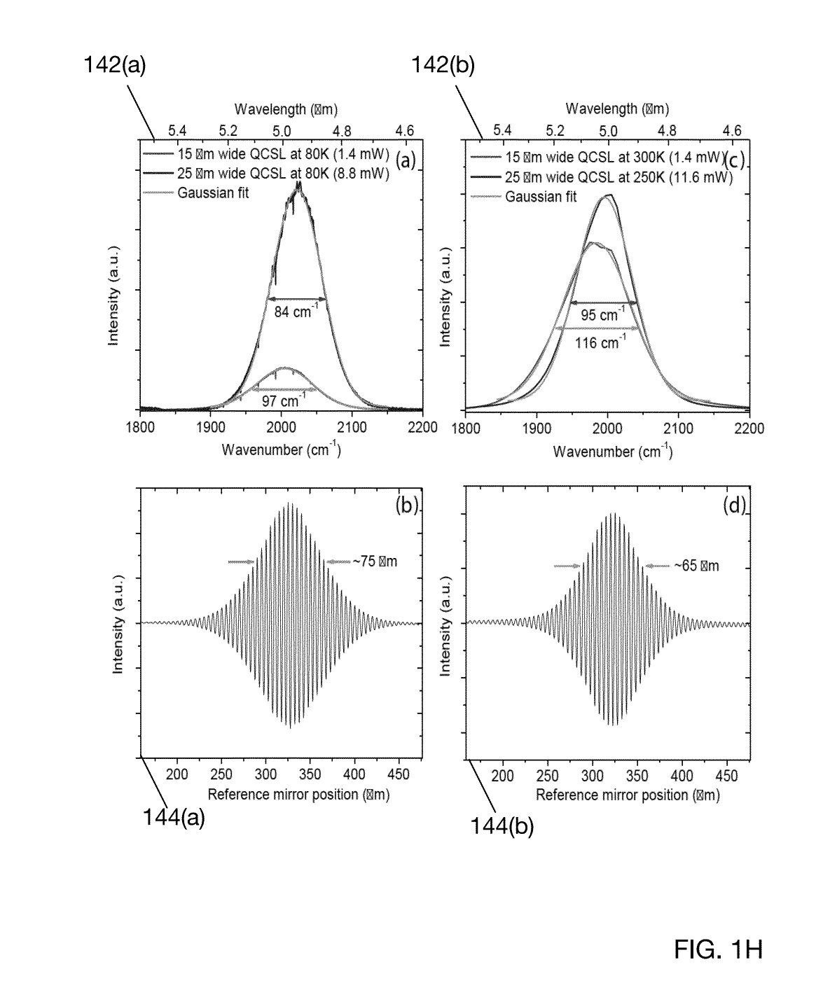

FIG. 1A depicts an exemplary embodiment of a QC SL emitter employing low-reflectivity facets. According to the embodiment depicted in FIG. 1A, QCSL emitter 100 comprises semiconductor cavity 102 and two low reflectivity facets, 108(a) and 108(b). According to one embodiment semiconductor cavity 102 may comprise a III-V semiconductor wafer grown by Metalorganic Chemical Vapour Deposition (“MOCVD”) processes.

Semiconductor cavity 102 is coupled to first low-reflectivity facet 108(a) and a second low-reflectivity facet 108(b). Although FIG. 1A shows semiconductor cavity 102 as having a linear configuration, dashed line 150 is meant to illustrate that according to multiple embodiments described herein semiconductor cavity 102 may be arranged in a myriad of topological and/or geometrical configurations, which operate to increase the length of the cavity thereby maximizing ASE intensity while simultaneously maintaining a compact design. As will be described in more detail below, according to multiple embodiments described herein semiconductor cavity 102 is arranged in a spiral geometry. Although not shown in FIG. 1A, semiconductor cavity 102 may further comprise a plurality of thin layers forming a superlattice.

II. Linear Geometry with Tilted Cleaved Facet and Rounded Shaped Wet-Etched Sloped Facet

FIG. 1B depicts an exemplary embodiment of a QCSL emitter employing a linear semiconductor cavity, a tilted cleaved facet and a rounded shaped wet-etched sloped facet. As shown in FIG. 1B, QCSL emitter 100 comprises linear semiconductor cavity 102, tilted cleaved facet (“TCF”) 106 (front facet) and rounded shaped wet-etched sloped facet (“RSWESF”) 104 (back facet). RSWESF 104 greatly reduces optical feedback by reflecting light into the substrate (not shown in FIG. 1B) and by scattering the incident light within the curved wall of rounded wet etched sloped facet 104.

FIG. 1C is a scanning electron microscope (“SEM”) of a portion of linear semiconductor cavity 102 coupled to RSWESF 104 according to one embodiment. FIG. 1C shows RSWESF 104 comprising wet-etched sloped portion 160, semiconductor 162 and metal material 164, which according to one embodiment is gold. A ridge cavity tilted from the cleavage plane by 17° is used to suppress the residual reflection from the front facet, which may be TCF 106.

A. Facet Structure and Reflectivities

According to one embodiment, the reflectivity RSWESF 104 shown in FIG. 1B-1C is at least approximately 10-4. The output power of SCSL device 100 may be further enhanced by the addition of a Si3N4 layer on RSWESF 104 as an anti-reflection (“AR”) coating. The refractive index of Si3N4 is 1.97 at λ=5 μm, close to the optimum refractive index of 1.83 for an AR coating. In particular, according to one embodiment, approximately 1.2 μm of Si3N4 may be deposited with plasma enhanced chemical vapor deposition (“PECVD”) on RSWESF.

According to one embodiment, a ridge cavity is tilted from the cleavage plane by 17° and provides suppression of the residual reflection from TCF 106. The 17° tilt angle falls below the critical angle (approximately 18°) of total internal reflection of the material utilized in QCSL emitter 100 and provides reflectivity as low as approximately 0.01.

B. QC Structure and Fabrication

According to one embodiment, the QC structure for QCSL emitter 100 may be grown by metal organic chemical vapor deposition (“MOCVD”) on an InP substrate using strain-balanced In 0.66 Ga 0.34 As/Al 0.69 In 0.31 As material. According to this embodiment, 40 repetitions of an injector/active region are sandwiched by low doped (cm-3) InP claddings layers. According to this same embodiment, each injector region may utilize a sheet doping density of 1.1011 cm-2. The waveguides may be patterned by photolithography and wet-etched to approximately 6 μm deep.

According to one embodiment QCSL emitter 100 utilizes an “ultrastrong coupling” scheme, employing a thin injection barrier (approximately 10 Å), which increases the energy splitting between the injector ground level and the upper laser level (15 meV compared to approximately 5 meV in conventional designs) and improves electron transport.

FIG. 1D shows an exemplary QC band structure at an applied electric field of 95 kV cm⁻¹ for a QCSL emitter device utilizing a linear geometry for approximately 5 μm wavelength emission according to one embodiment. Referring to FIG. 1D, according to one embodiment starting from the widest quantum well, an exemplary layer sequence of one period of the active and injector regions in the electron downstream direction (nanometers) is:

4.2/1.15/3.9/1.4/3.4/2/2.8/1.65/2.3/1.5/1.9/1.3/1.8/1.5/1.75/1.7/1.6/1.65/1.4/1.4/1.1/1.15,

where the In_{0.31}Al_{0.69}As barriers are in bold, and the In_{0.66}Ga_{0.34}As wells are in normal text. According to one embodiment, the underlined layers are doped with a doping density of 1.5×10¹⁷ cm⁻³. State pairs 132(a)-132(d) shown in FIG. 1D illustrate coupled injector ground levels and upper laser levels, which have a 15 meV energy splitting. FIG. 1D also shows lower laser levels 134.

C. Exemplary Dimensions

According to one embodiment, QCSL emitter 100 employing linear cavity 102 may be fabricated at an exemplary length of 8 mm long and a width of either 15 μm or 25 μm. According to one embodiment, these exemplary lengths were chosen accordingly to achieve milliwatt ASE power while keeping the threshold current within the capacity of the current source used at room temperature. However, it will be understood that these dimensions are merely exemplary and not intended to limit the scope of the invention described herein.

D. Experimental Results

FIG. 1E a shows a representative pulsed light, current, and voltage (“LIV”) characteristic of a 15 μm wide and 8 mm long tilted linear QCSL device employing a TCF front facet and a RCWESF back facet at various temperatures according to one embodiment. The “x” on the light current curves indicate the laser threshold. LIV measurements were taken in pulsed-mode with a pulse width of 100 ns and a repetition rate of 5 kHz. The light from TCF 106 was collimated and focused by a pair of ZnSe lenses onto a calibrated room temperature HgCdTe detector. As shown in FIG. 1E, according to one embodiment a 15 μm wide linear QCSL device employing a TCF 106 front facet and a RCWESF 104 back facet with no Si₃N₄ coating emits a peak superluminescence output power of 1.8 mW at 80 K and 1.5 mW at 300 K, with the threshold current of 1.7 A (1.4 kA/cm²) and 6 A (5 kA/cm²) respectively. FIG. 1E also illustrates that the optical peak power is relatively insensitive to the device temperature. A room temperature far-field measurement, taken at 5.6 A with a liquid-nitrogen-cooled HgCdTe detector, shows multiple intensity peaks with a FWHM of around 55°.

As shown in FIG. 1G, a significant improvement in the performance of the Si₃N₄ coated 25 μm wide QCSL device is observed compared to the non-AR coated one. In particular, the latter emits an optical peak output power of 3.8 mW at 80 K and 3.9 mW at 250 K.

FIG. 1F shows a far-field intensity pattern of a linear QCSL device employing a TCF front facet and a RSWESF back facet according to one embodiment.

FIG. 1G is a plot showing a comparison of superluminescence output power for a 25 μm wide and 8 mm long linear QCSL device employing a TCF front facet and a RCWESF back facet that is AR coated and one that is not AR coated at various temperatures according to one embodiment. Referring to FIG. 1G the solid line shows coated QCSL device 100 while the dashed line shows an uncoated QCSL device 100. The “x” on the light current curve indicates the laser threshold. 10

FIG. 1H shows various plots of emission spectra for a QCSL device employing a linear cavity, a TCF front facet and a RCWESF back facet according to one embodiment. Referring to FIG. 1H, 142(a) shows a high resolution (0.125 cm⁻¹) emission spectra of 15 μm and 25 μm wide linear QCSL devices employing a TCF front facet and a RCWESF back facet at threshold obtained by Fourier Transform Infrared Spectrometry (“FTIR”) in fast-scan mode (80 K) and associated Gaussian fits of spectra.

144(a) shows an interferogram of a 15 μm wide linear QCSL device employing a TCF front facet and a RCWESF back facet at threshold at 80 K. The emission spectra shown in 144(a) was measured at the threshold with a FTIR with 16 cm⁻¹ resolution in the slow scan mode.

142(b) shows emission spectra of a 15 μm (300 K) and 25 μm (250 K) wide linear QCSL devices employing a TCF front facet and a RCWESF back facet at threshold in step scan (16 cm⁻¹ resolution) and associated Gaussian fits of spectra.

144(b) shows an interferogram of a 15 μm wide linear QCSL device employing a TCF front facet and a RCWESF back facet at threshold at 300 K.

According to one embodiment, linear QCSL devices employing a TCF front facet and a RCWESF back facet, achieve room temperature operation with optical peak powers of ASE of more than 1 mW and lower temperature optical powers of more than 10 mW up to 250K limited by the employed power supply.

III. Spiral Geometry

As noted previously, it is desirable to increase the length of linear semiconductor cavity 102 for SCSL devices in order to increase ASE intensity. In particular, longer devices are required to generate higher SL power since the maximum attainable SL power increases approximately linearly with an increase in the device length.

In order to address these constraints, Applicants have devised a spiral cavity design in a SCSL device, which provides compactness and therefore enables the fabrication of longer devices without the need for greater chip area.

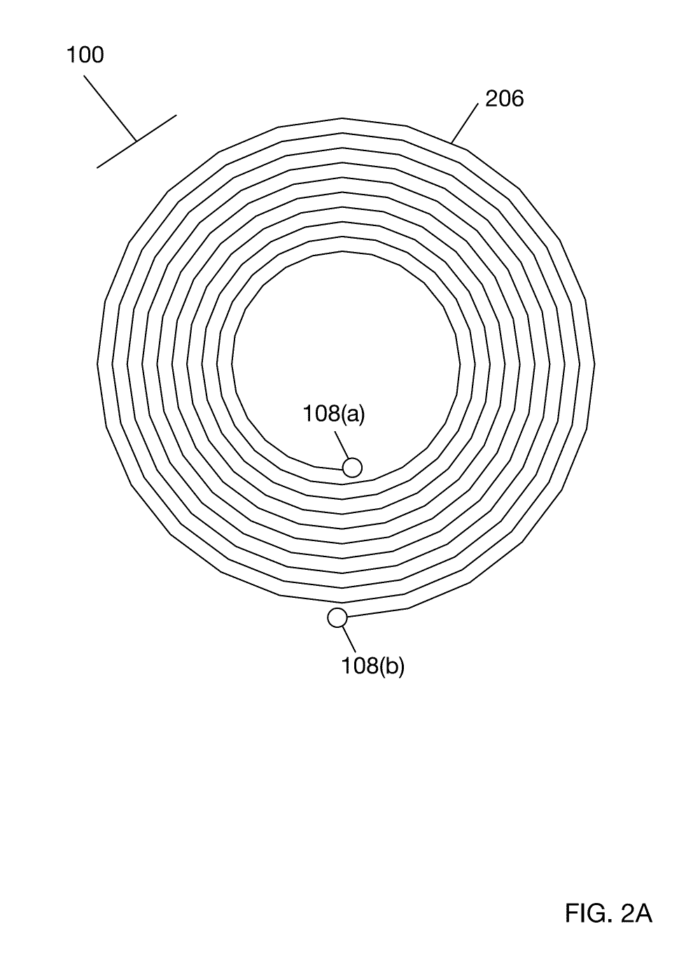

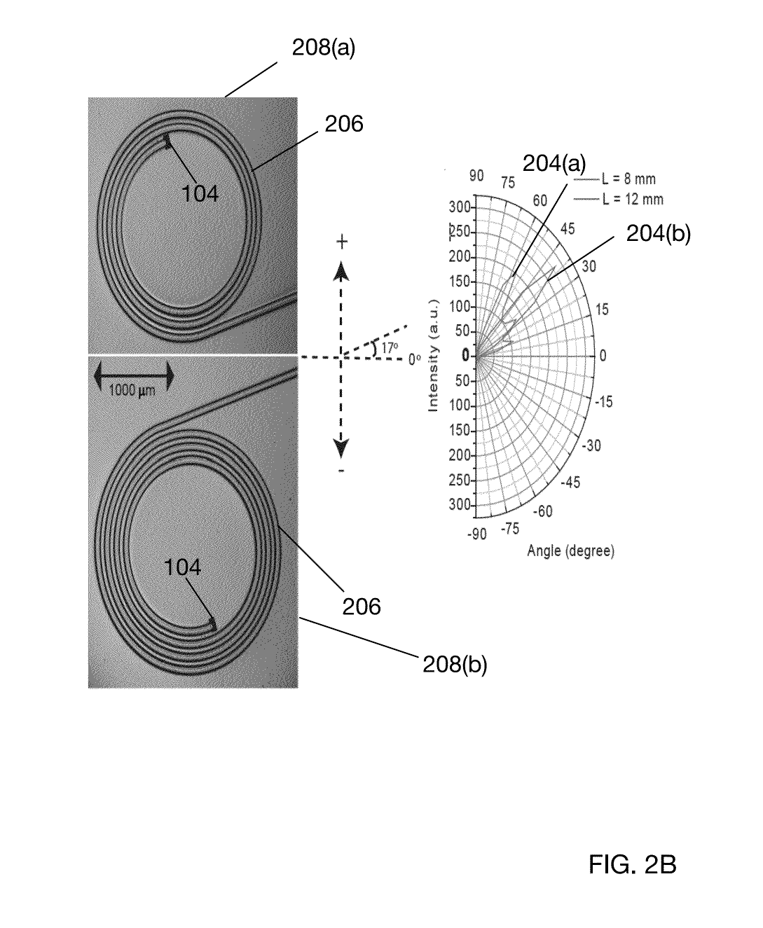

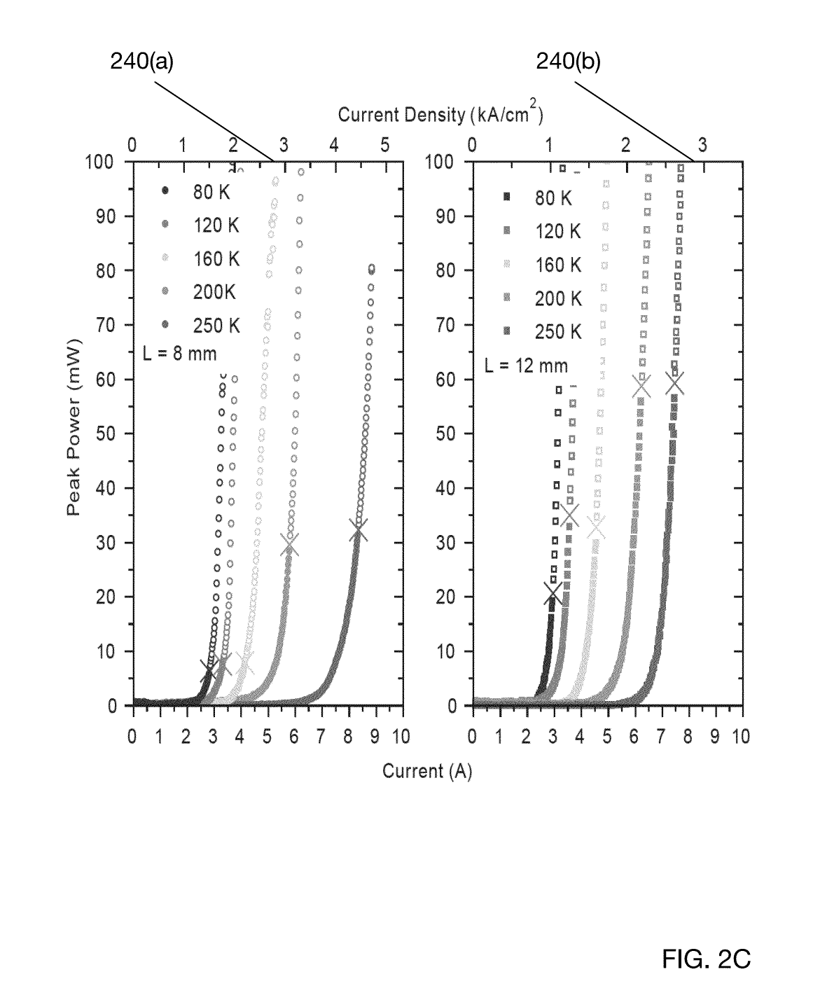

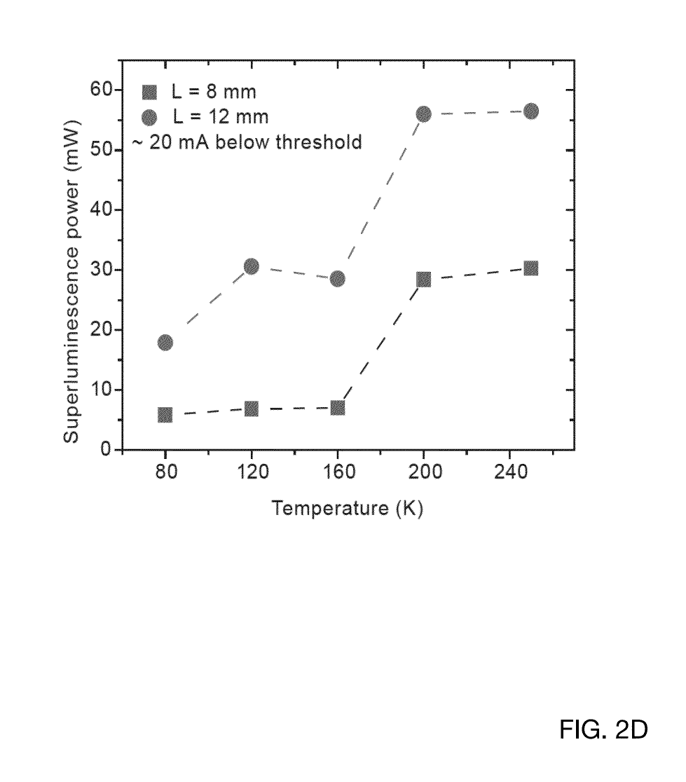

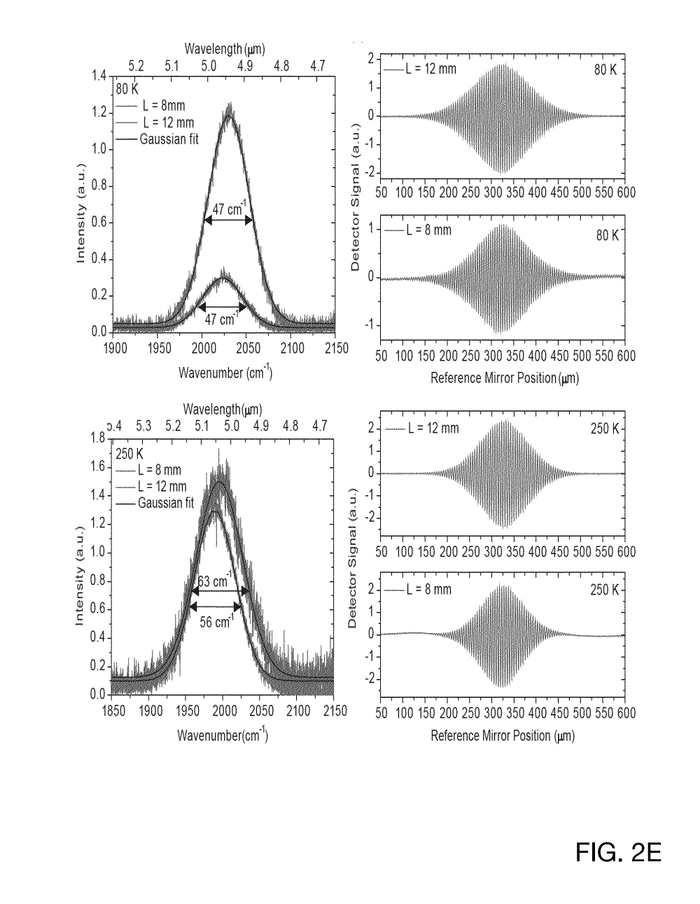

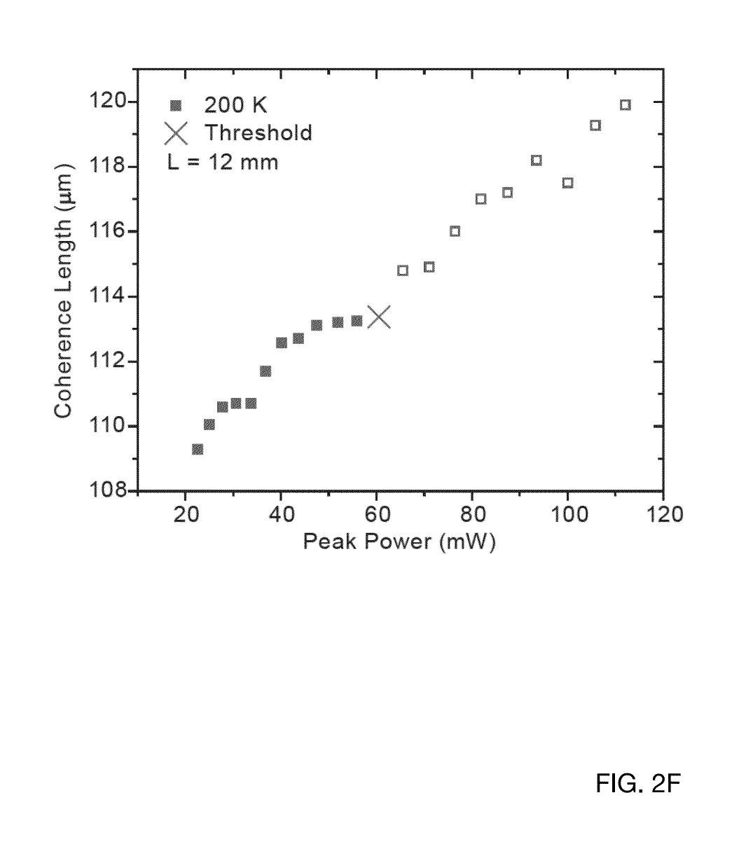

FIG. 2A depicts a QCSL device employing a superluminescent spiral cavity coupled to two low-reflectivity facets according to one embodiment. In particular, referring to FIG. 2A, QCSL device 100 further comprises spiral semiconductor cavity 206 and facets 108(a) and 108(b). As previously noted, the embodiment depicted in FIG. 2A employing spiral semiconductor cavity 206 with a large bend radius (as opposed to a linear cavity) is employed to provide a longer cavity thereby generating more power while simultaneously allowing for a more compact fabrication of longer devices.

IV. Spiral Geometry with Tilted Cleaved Facet and Rounded Shaped Wet-Etched Sloped Facet

FIG. 2B shows optical images of a portion of QCSL devices employing a spiral cavity (one of 8 mm and another 12 mm) as well as respective far-field intensity measurements for these devices according to one embodiment. According to one embodiment a SCSL device comprises a spiral semiconductor cavity 206 coupled to RSWESF 104 (back facet), and a 17° angled straight section with a TCF 106 (front facet) (not shown in FIG. 2B). FIG. 2B illustrates two exemplary embodiments of different cavity lengths, 8 mm (208A) and 12 mm (208B). In particular, 206(a) shows an optical microscope image of a spiral cavity coupled to RSWESF 104 with a total length of 8 mm according to one embodiment. 206(b) shows an optical microscope image of a spiral cavity coupled to RSWESF 104 with a total length of 12 mm according to one embodiment.

204(a) shows far-field intensity measurements taken at 80 K of an SCSL device employing a spiral cavity of length 8 mm coupled to RSWESF 104 according to one embodiment. 204(b) shows far-field intensity measurements taken at 80 K of an SCSL device employing a spiral cavity of length 12 mm coupled to RSWESF 104 according to one embodiment. As shown in 204(a) and 204(b), the light emission of both devices exhibit two peaks in the positive angle direction, with a full width at half maximum (“FWHM”) of approximately 15° and approximately 35° for 8 mm and 12 mm devices respectively.

A. Facet Structure and Reflectivities

According to one embodiment RSWESF 104 is additionally coated with 1.2 μm of Si₃N₄ to further suppress the optical feedback from RSWESF 104. The reflectivity of such a facet with the AR coating is experimentally determined to be approximately 10⁻⁵. A 17° angled ridge waveguide serves to suppress the residual reflection from the front facets and according to one embodiment, achieves a reflectivity of approximately 10⁻².

B. QC Structure and Fabrication

According to one embodiment a QCSL device employing a spiral cavity coupled to a RSWESF 104 (back facet), and a 17° angled straight section with a TCF 106 (front facet) utilizes an ultra-strong coupling scheme with an emission wavelength of approximately 5 μm at 80 K. According to one embodiment, the devices may be fabricated using standard ridge-laser processing. In particular, according to one embodiment, the waveguides may be patterned by photolithography and wet-etched to approximately 6 μm deep. According to this same embodiment, 1.2 μm of Si₃N₄ is deposited with PECVD. Contact windows of approximately 18 μm in width are opened at the top of the cavities (excluding the back facet) with photolithography and reactive-ion etching (“RIE”). Contact patterns are again defined by photolithography and Ti/Au top metal contact of 30/300 nm is deposited through electron-beam evaporation from three different angles to ensure coverage on all sidewalls of the spiral shaped cavity. After lift-off, the substrate may be thinned to approximately 200 μm and 20/200 nm of Ge/Au bottom metal contact is deposited through electron-beam evaporation. The devices may then be mounted epitaxial side up to copper heat sinks.

C. Exemplary Dimensions

According to one embodiment, the lengths of the 17° angled straight ridges are may be 950 μm for the 8 mm device and approximately 1325 μm for the 12 mm device. Both of the waveguides may be approximately 25 μm in width and approximately 6 μm in depth, deep enough to expose the active core while maintaining a slope at RSWESF 104 in the active region to reflect incident light into the substrate and to scatter the incident light with its curved wall (not shown in FIG. 2B).

According to one embodiment, the minimum spiral radius is chosen to be approximately 380 μm for negligible bending losses.

D. Experimental Results

FIG. 2C is a plot of peak power vs. current taken under pulsed operation (100 ns pulse width at 5 kHz) across different temperatures for an 8 mm QCSL device and 12 mm QCSL device both employing spiral cavities and a RSWESF according to on embodiment. In particular, 240(a) is a plot of peak power vs. current taken across different temperatures for an 8 mm QCSL device employing a spiral cavity according to one embodiment. 240(b) is a plot of peak power vs. current taken across different temperatures for a 12 mm QC SL device employing a spiral cavity according to one embodiment. In both plots, the “X” marks the laser threshold. Close (open) symbols indicate the power below(above) threshold.

FIG. 2D is a plot of superluminescence power of a QCSL device employing a spiral cavity and a RSWESF taken at approximately 20 mA below the laser threshold vs. temperature. Squares and circles correspond to the 8 mm and 12 mm device, respectively.

FIG. 2E shows plots of ASE spectra and interferograms at approximately 20 mA below threshold for 8 mm and 12 mm SCSL devices employing a spiral cavity and an RSWESF according to one embodiment.

FIG. 2F is a plot of coherence length vs. peak power of a 12 mm QC SL device employing a spiral cavity and RSWESF at 200 K according to one embodiment. The “X” marks the laser threshold.

V. Spiral Geometry with Tilted Cleaved Facet and Rounded Shaped Passive Loop Facet

According to one embodiment, in order to minimize the back facet reflectivity without relying on an AR coating, an un-pumped loop back facet dominated by waveguide loss may be used as a back facet. Such a loop back facet may be employed for the purpose of absorption in order to suppress the back facet reflectivity. By replacing AR coated RSWESF 104 of a spiral cavity 206 (described above with reference to FIG. 2A-2F) with a passive loop facet, the lasing threshold density may be suppressed due to a decrease in the back facet reflectivity. According to one embodiment, as will be discussed below utilization of a passive loop facet allows at least a two-fold increase in the peak superluminescent power as compared to employing a 16 mm long spiral cavity alone.

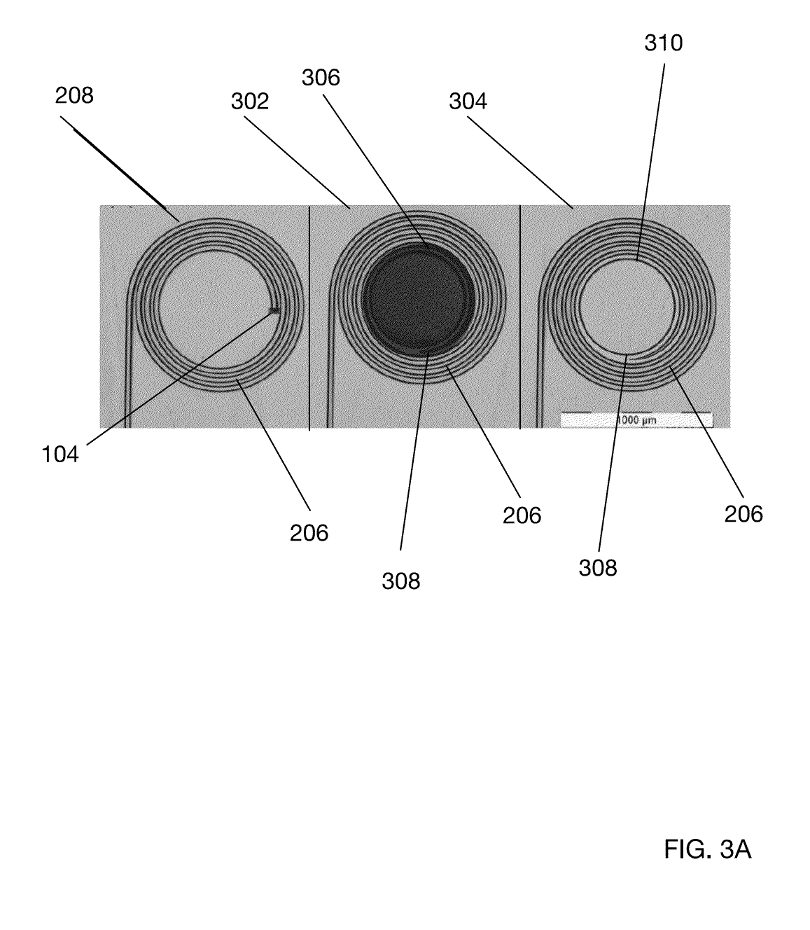

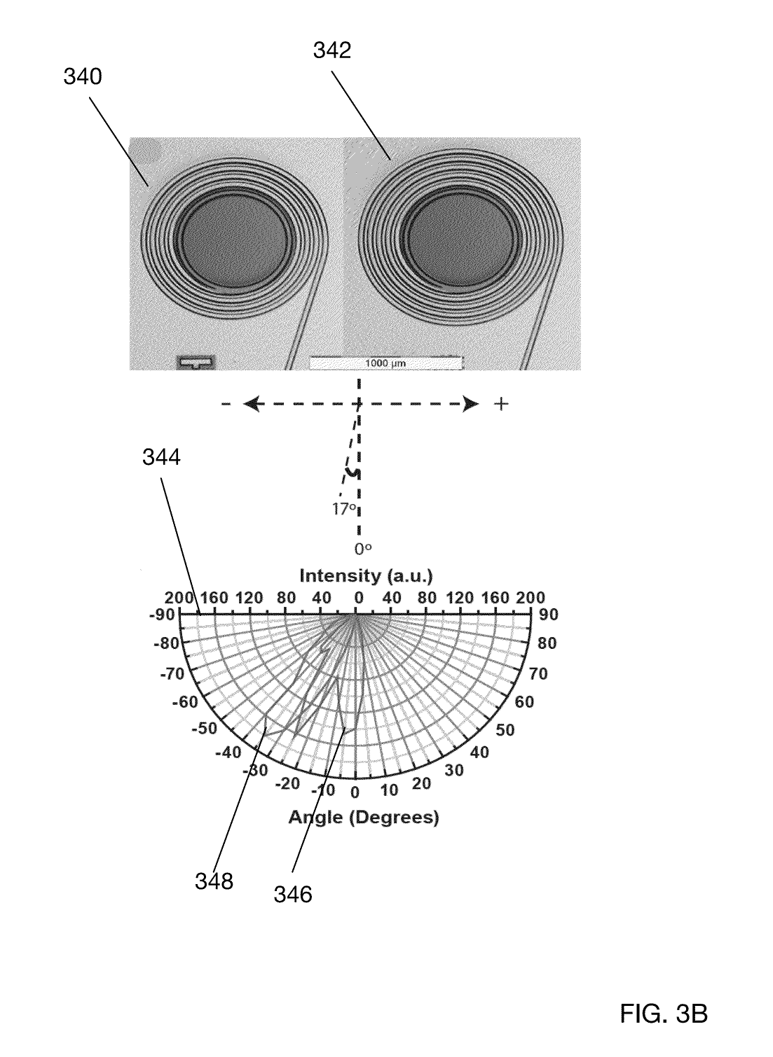

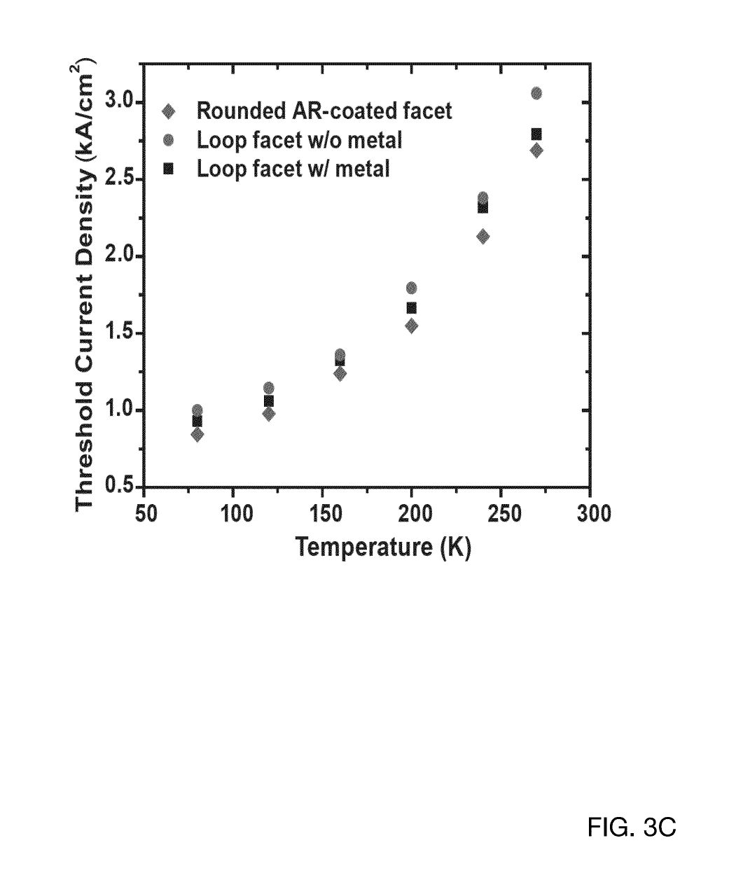

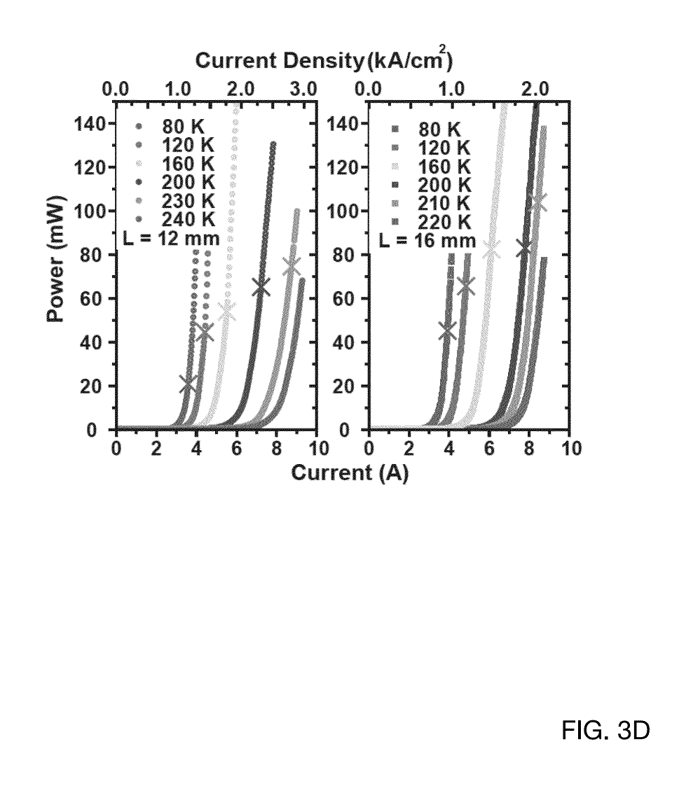

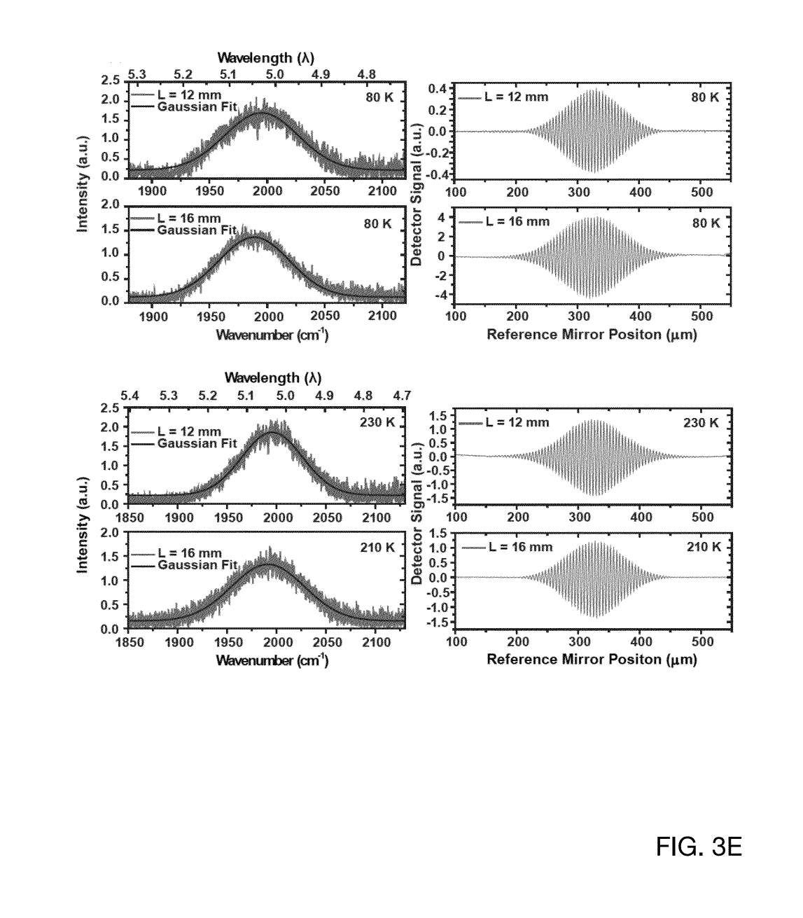

FIG. 3A is an optical image of several different portions of spiral cavity QCSL devices joined to non-tilted ridge waveguides according to one embodiment.

In particular, 208 shows a portion of a QCSL device employing spiral cavity 206 and RSWESF 104 AR coated back facet according to one embodiment.

302 shows a portion of a QCSL device employing spiral cavity 206 and passive loop back facet that does not utilize metal 306 according to one embodiment. In particular referring to 302, 306 is a loop back facet that does not utilize metal. 308 is a Y-splitter where spiral cavity joins loop back facet that does not utilize metal 306.

304 shows a portion of a QCSL device employing spiral cavity 206 and passive loop back facet that does utilize metal 310 according to one embodiment. In particular referring to 304, 310 is a loop back facet that does utilize metal. 308 is a Y-splitter where spiral cavity joins loop back facet that does utilize metal 310.

FIG. 3B shows microscope images of a portion of two QCSL devices employing spiral cavities and a passive loop back facet with a total length of 12 mm (left) and 16 mm (right). In particular, 340 is a microscope image of a portion of a 12 mm QCSL device employing a spiral cavity and a passive loop back facet. 342 is a microscope image of a portion of a 16 mm QCSL device employing a spiral cavity and a passive loop back facet.

344 is a plot of far-field measurements taken at 80 K of the 12 mm device 346 and the 16 mm device 348, both taken at subthreshold current in pulsed mode.

A. Facet Structure and Reflectivities

Using the independently measured gain of the QC laser material, the back loop facet, reflectivities of the cavity and facet designs shown in FIG. 3A (i.e., AR coated RSWESF, loop facet without metal and loop facet with metal) the respective reflectivities were determined to be 10⁻⁶, 10⁻⁸, and 10⁻⁷ at 80 K, respectively. Therefore, by incorporating a passive loop facet into the spiral cavity design together with a 17° tilted front facet, threshold current density can be further suppressed and thereby increase the peak SL power.

B. QC Structure and Fabrication

According to one embodiment, the QC structure and fabrication process utilized a scheme similar to that described above with respect to the spiral cavity design employing a RSWESF rather than a passive loop back facet.

C. Experimental Results

FIG. 3C is a plot of current density vs. temperature comparing QCSL devices employing a spiral cavity and an AR RSWESF, a passive loop back facet without metal and a passive loop back facet with metal according to one embodiment.

FIG. 3D shows plots of peak power vs. current a 12 mm and 16 mm QCSL device employing a spiral cavity and a passive loop back facet according to one embodiment. The measurements were taken under pulsed operation (100 ns pulse width at 5 kHz) across different temperatures for the 12 mm device (left, circles) and the 16 mm device (right, squares). The “X” marks the laser threshold. Close (open) symbols indicate the power below (above) threshold.

FIG. 3E show ASE spectra and interferograms at various temperatures of a 12 mm and 16 mm QCSL device employing a spiral cavity and a passive loop back facet according to one embodiment.

Although preferred embodiments of the invention have been described using specific terms, such description is for illustrative purposes only, and it is to be understood that changes and variations may be made without departing from the spirit or scope of the following claims.

What is claimed is:

1. A quantum cascade emitter, comprising:
a. a cavity comprised of a semiconductor material;
b. a first low-reflectivity facet coupled to a first end of said cavity; and,
c. a second low-reflectivity facet coupled to a second end of said cavity.

2. The quantum cascade emitter according to claim 1, wherein at least one of the said first low reflectivity facet and the said second low reflectivity facet is comprised of an anti-reflective material.

3. The quantum cascade emitter according to claim 2, wherein said anti-reflective material comprises silicon nitride.

4. The quantum cascade emitter according to claim 1, wherein said cavity is arranged in a spiral shape.

5. The quantum cascade emitter according to claim 1, wherein said first low-reflectivity facet comprises a tilted cleaved facet, wherein an angle between a centerline of said cavity and a line normal to a face of said first low-reflectivity facet is greater than zero.

6. The quantum cascade emitter according to claim 5, wherein said angle is less than or equal to a Brewster angle associated with the cavity.

7. The quantum cascade emitter according to claim 1, wherein said semiconductor material comprises at least two thin layers.

8. The quantum cascade emitter according to claim 1, wherein said second low-reflectivity facet comprises a rounded shaped wet-etched sloped facet.

9. A method for generating a high power superluminescent light in a quantum cascade device, comprising:
a. terminating a semiconductor cavity at a first end with a rounded shaped wet-etched sloped facet; and
b. terminating said semiconductor cavity at a second end with a tilted cleaved facet, second tilted cleaved facet allowing light to exit from said cavity.

10. The method according to claim 9, further comprising arranging the cavity in a spiral shape.

11. The method according to claim 7, wherein said semiconductor material is arranged in at least two thin layers.

12. The method according to claim 7, wherein at least one of the rounded shaped wet-etched sloped facet and the tilted cleaved facet is comprised of an anti-reflective material.

13. The method according 12, wherein said anti-reflective material is comprised of silicon nitride.

14. The method according to claim 9, wherein said semiconductor cavity is at least about 4 mm in length and a product of a first reflectivity coefficient associated with the rounded shaped wet-etched sloped facet and a second reflectivity coefficient associated with the tilted cleaved facet, is less than about 10⁻⁴.

15. A quantum cascade emitter, comprising:
a. a spiral cavity comprised of a semiconductor material;
b. a first low-reflectivity facet coupled to a first end of said spiral cavity; and,
c. a second low-reflectivity element coupled to a second end of said spiral cavity.

16. The quantum cascade emitter according to claim 15, wherein the second low-reflectivity element is a rounded shaped wet-etched sloped facet.

17. The quantum cascade emitter according to claim 15, wherein the second low-reflectivity element is a passive loop facet.

18. The quantum cascade emitter according to claim 15, wherein said first low-reflectivity facet comprises a tilted cleaved facet, wherein an angle between a centerline of said cavity and a line normal to a face of said first low-reflectivity facet is greater than zero.

19. The quantum cascade emitter according to claim 15, wherein said first low reflectivity facet is comprised of an anti-reflective material.

20. The quantum cascade emitter according to claim 19, wherein said anti-reflective material comprises silicon nitride.
